(19) United States
(12) Patent Application Publication
(10) Pub. No.: US 2026/0005152 A1
(43) Pub. Date: Jan. 1, 2026

(54) MEMORY MODULE

(71) Applicant: Samsung Electronics Co., Ltd., Suwon-si (KR)

(72) Inventors: Jaekwang Lee, Suwon-si (KR); Jaeseok Jang, Suwon-si (KR); Taeyeong Kim, Suwon-si (KR); Hyuna Lee, Suwon-si (KR); Dongmin Jang, Suwon-si (KR)

(21) Appl. No.: 19/022,113

(22) Filed: Jan. 15, 2025

(30) Foreign Application Priority Data
Jun. 27, 2024 (KR) 10-2024-0084822

(51) Int. Cl. H01L 23/538; H01L 23/498; H01L 25/18; H10B 80/00; H10D 80/30

(52) U.S. Cl. CPC H01L 23/5386; H01L 23/49866; H01L 23/5383; H01L 25/18; H10B 80/00; H10D 80/30

(57) ABSTRACT

A memory module includes a module substrate, and a memory device on a front surface of the module substrate, wherein the module substrate includes a plurality of insulating layers, a plurality of rear surface connection pads, and an outer edge dummy layer on the plurality of insulating layers, wherein the plurality of rear surface connection pads include a first metal layer, a second metal layer, and a third metal layer, wherein the first metal layer includes copper, the second metal layer includes nickel, and the third metal layer includes gold, wherein the outer edge dummy layer extends along an outer edge of the rear surface of the module substrate, and wherein the plurality of rear surface connection pads are in contact with a plurality of connector pins in an external compression mounting connector, respectively.

### CROSS-REFERENCE TO RELATED APPLICATION

This application is based on and claims ranking under 35 U.S.C. § 119 to Korean Patent Application No. 10-2024-0084822, filed on Jun. 27, 2024, in the Korean Intellectual Property office, the disclosure of which is incorporated by reference herein in its entirety.

### BACKGROUND

The inventive concept relates to a memory module.

The use of RAMs is common in various digital devices. In particular, DRAMs are used in general PCs, servers, laptops, tablet PCs, etc. Dual in-line memory modules (DIMMs) and small outline dual in-line memory modules (SO-DIMMs) smaller than the DIMMs are generally used as memory modules in the general PCs. Alternatively, electronic devices equipped with on-board type memories are also used instead of the memory modules according to the specifications described above. The specifications of existing memory modules, including DIMMs and SO-DIMMs, are such that the existing memory modules are detachable from the electronic devices, but have relatively large sizes and thicknesses, and in the case of the on-board type memories, the on-board type memories have high space efficiency, but are difficult to attach and detach.

In addition to the miniaturization of electronic devices, a memory module specification of low power compression attached memory module (LPCAMM2) has been proposed which can take advantage of the benefits while supplementing the shortcomings of the existing memories according to the existing specifications and the on-board type memories. The LPCAMM2 is superior to existing memory module specifications in terms of space efficiency and power management efficiency. Unlike existing memory modules with connectors on one side, the LPCAMM2 may transceive electrical signals more smoothly because the connector is close to the memory device located on the memory module, and is relatively small in size compared to the specifications of the existing memory module.

A rear surface connection pad contacting the connector is provided on the rear surface where the memory device of the memory module of the LPCAMM2 is not arranged. The rear surface connection pad is generally formed by performing gold plating by using an electroless plating. Because the thickness of the gold plating performed by using the electroless plating is limited, there is a risk of corrosion in the rear surface connection pad of the memory module of the LPCAMM2.

### SUMMARY

Embodiments of the inventive concept may provide a memory module with improved corrosion reliability.

Issues to be solved by the inventive concept are not limited to the above-mentioned issues, and other issues not mentioned may be clearly understood by those of ordinary skill in the art from the following descriptions.

According to an aspect of the inventive concept, there is provided a memory module including a module substrate, and a memory device on a front surface of the module substrate, wherein the module substrate includes a plurality of insulating layers, a plurality of wirings inside the plurality of insulating layers, a plurality of rear surface connection pads on the plurality of insulating layers on a rear surface, which is opposite to the front surface of the module substrate, an outer edge dummy layer on the plurality of insulating layers, and a solder resist on the plurality of insulating layers, wherein the plurality of rear surface connection pads include a first metal layer, a second metal layer, and a third metal layer, and the first metal layer, the second metal layer, and the third metal layer are sequentially stacked from the plurality of insulating layers, wherein the first metal layer, the second metal layer, and the third metal layer include different materials from each other, wherein the outer edge dummy layer extends along an outer edge of the rear surface of the module substrate, wherein the plurality of rear surface connection pads are configured to contact a plurality of connector pins, respectively, which are provided in an external compression mounting connector, and wherein a thickness of the third metal layer is about 0.7 μm to about 3.0 μm in a direction perpendicular to the front surface of the module substrate.

In addition, according to another aspect of the inventive concept, there is provided a memory module including a module substrate, a plurality of memory devices on a front surface of the module substrate, and power management integrated circuits (PMICs) spaced apart from each other in one side direction of the plurality of memory devices and adjacent to each other, and a memory controller chip, wherein the module substrate includes a plurality of insulating layers, a plurality of wirings inside the plurality of insulating layers, a plurality of rear surface connection pads on the plurality of insulating layers on a rear surface of the module substrate, which is opposite to the front surface of the module substrate, an outer edge dummy layer on the plurality of insulating layers, and a solder resist on the plurality of insulating layers, wherein the plurality of rear surface connection pads include a plurality of first rear surface connection pads and a plurality of second rear surface connection pads, wherein an area of the plurality of second rear surface connection pads is a circular shape in a plan view of the memory module, wherein the circular shape partially overlaps another circular shape smaller than the circular shape, wherein the plurality of rear surface connection pads include a first metal layer, a second metal layer, and a third metal layer, the first metal layer, the second metal layer, and the third metal layer are sequentially stacked from the plurality of insulating layers, and the first metal layer includes copper, the second metal layer includes nickel, and the third metal layer includes gold, wherein the outer edge dummy layer is laterally spaced apart from the plurality of rear surface connection pads, and continuously extends along an entire outer edge of the rear surface of the module substrate, wherein the outer edge dummy layer is not electrically connected to the plurality of rear surface connection pads and the plurality of wirings, wherein the plurality of rear surface connection pads are configured to contact a plurality of connector pins in an external compression mounting connector, respectively, and wherein a thickness of the third metal layer is about 0.7 μm to about 3.0 μm in a direction perpendicular to the front surface of the module surface.

In addition, according to another aspect of the inventive concept, there is provided a memory module including a module substrate, and a memory device on a front surface of the module substrate, wherein the module substrate includes a plurality of insulating layers, a plurality of wirings inside the plurality of insulating layers, a plurality of rear surface connection pads on the plurality of insulating layers on a rear surface, which is opposite to the front surface of the module substrate, an outer edge dummy layer on the plurality of insulating layers, and a solder resist on the plurality of insulating layers, wherein the plurality of rear surface connection pads include a first metal layer, a second metal layer, and a third metal layer, and the first metal layer, the second metal layer, and the third metal layer are sequentially stacked from the plurality of insulating layers, wherein the first metal layer includes copper, the second metal layer includes nickel, and the third metal layer includes gold, wherein the outer edge dummy layer extends along an outer edge of the rear surface of the module substrate, wherein the plurality of rear surface connection pads are configured to contact a plurality of connector pins in an external compression mounting connector, respectively, wherein a vertical thickness of the third metal layer is about 0.7 μm to about 3.0 μm in a direction perpendicular to the front surface of the module substrate, wherein the outer edge dummy layer includes a first outer edge metal layer, a second outer edge metal layer, and a third outer edge metal layer, wherein the first outer edge metal layer, the second outer edge metal layer, and the third outer edge metal layer are sequentially stacked from the plurality of insulating layers, wherein the first outer edge metal layer includes copper, the second outer edge metal layer includes nickel, and the third outer edge metal layer includes gold, wherein the outer edge dummy layer is laterally spaced apart from the plurality of rear surface connection pads, is not electrically connected to the plurality of rear surface connection pads and the plurality of wirings, and continuously extends along an entire outer edge of the module substrate, wherein the memory device is not on the rear surface of the module substrate, and a first area, a second area, and a third area, which include an area in which the memory device is arranged, is on the front surface of the module substrate, wherein the second area includes a memory controller chip, the third area includes a power management integrated circuit (PMIC), the second area is adjacent to the third area, and the second area and the third area are on one side of the first area, wherein at least portions of the plurality of rear surface connection pads overlap the first area in the direction perpendicular to the front surface of the module substrate, and all of the plurality of rear surface connection pads do not overlap the second area and the third area in the direction perpendicular to the front surface of the module substrate, wherein a thickness increases in an order of the first metal layer, the second metal layer, and the third metal layer in the direction perpendicular to the front surface of the module substrate, wherein a material included in the first outer edge metal layer, a material included in the second outer edge metal layer, a material included in the third outer edge metal layer are identical to a material included in the first metal layer, a material included in the second metal layer, a material included in the third metal layer, respectively corresponding thereto, and wherein a thickness of the solder resist in the direction perpendicular to the front surface of the module substrate is greater than a thickness of the plurality of rear surface connection pads in the direction perpendicular to the front surface of the module substrate, all of surfaces of the plurality of rear surface connection pads are in contact with the solder resist, and the solder resist is on at least a portion of one surface of the third metal layer of the plurality of rear surface connection pads.

### BRIEF DESCRIPTION OF THE DRAWINGS

Embodiments will be more clearly understood from the following detailed description taken in conjunction with the accompanying drawings in which:

FIG. 1 is a diagram of a front surface of a memory module, according to an embodiment;

FIG. 2 is a perspective view of a memory module mounted on a compression mount connector, according to an embodiment;

FIG. 3 is a diagram of a rear surface of a memory module and a partially enlarged view of the rear surface of the memory module, according to an embodiment;

FIG. 4 is an enlarged perspective view of a portion of a module substrate of a memory module, according to an embodiment;

FIG. 5 is a cross-sectional view of a module substrate of a memory module, according to an embodiment;

FIG. 6 is an enlarged perspective view of a portion of a module substrate of a memory module, according to an embodiment;

FIG. 7 is a flowchart describing a method of manufacturing a module substrate of a memory module, according to an embodiment; and

FIGS. 8A through 8G are cross-sectional views sequentially illustrating a method of manufacturing a module substrate of a memory module, according to embodiments.

### DETAILED DESCRIPTION OF THE EMBODIMENTS

Hereinafter, example embodiments of the inventive concept are described in detail with reference to the accompanying drawings. The same reference numerals are given to the same elements in the drawings, and repeated descriptions thereof are omitted. As used herein, the term “and/or” includes any and all combinations of one or more of the associated listed items. It will be understood that when an element is referred to as being “on,” “attached” to, “connected” to, “coupled” with, “contacting,” etc., another element, it can be directly on, attached to, connected to, coupled with or contacting the other element or intervening elements may also be present. In contrast, when an element is referred to as being, for example, “directly on,” “directly attached” to, “directly connected” to, “directly coupled” with or “directly contacting” another element, there are no intervening elements present. It will be understood that, although the terms “first”, “second”, etc. may be used herein to describe various elements or components, these elements or components should not be limited by these terms. These terms are only used to distinguish one element or component from another element or component. Therefore, a first element or component discussed below could be termed a second element or component without departing from the technical spirits of the present disclosure. It is noted that aspects described with respect to one embodiment may be incorporated in different embodiments although not specifically described relative thereto. That is, all embodiments and/or features of any embodiments can be combined in any way and/or combination. Embodiments of the inventive concept are provided to more completely explain the technical idea of the inventive to those of skill in the art, and the embodiments below may be modified in various different forms, and the scope of the technical idea of the inventive concept is not limited thereto. Rather, the embodiments are provided to make the inventive concept more faithful and complete, and to fully convey the idea of the technical idea of the inventive concept to those of skill in the art. In addition, the thickness or size of each layer in the drawings is exaggerated for convenience and clarity of explanation.

In the inventive concept, the first direction may be perpendicular to the second direction. The first direction and the second direction may be directions on a horizontal plane. A third direction may be perpendicular to both the first direction and the second direction. The upper surface of the specific object means one surface located in a positive third direction with respect to the specific object, and the lower surface of the specific object means one surface located in a negative third direction with respect to the specific object.

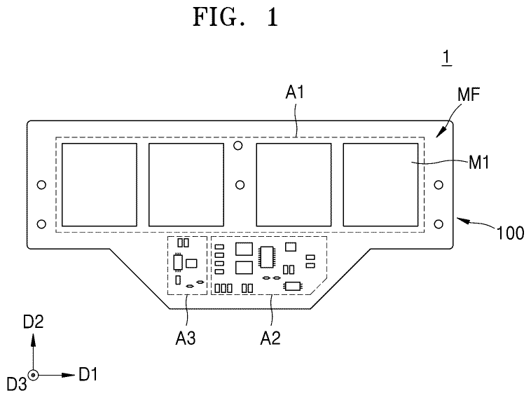

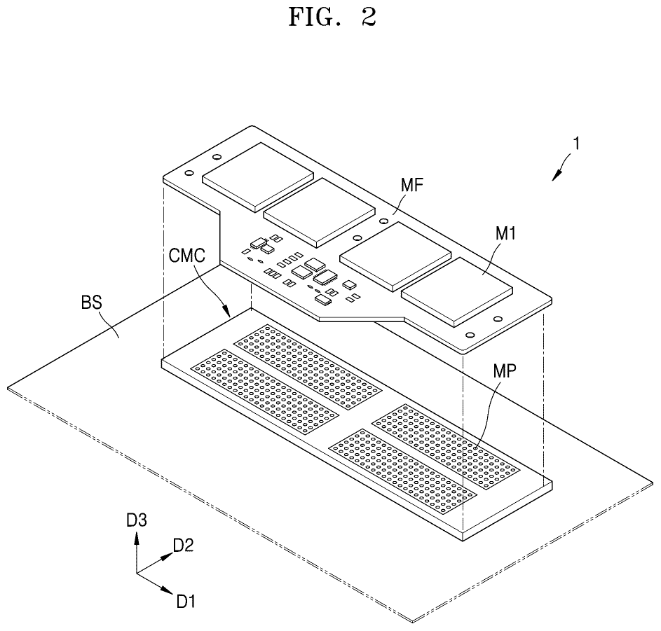

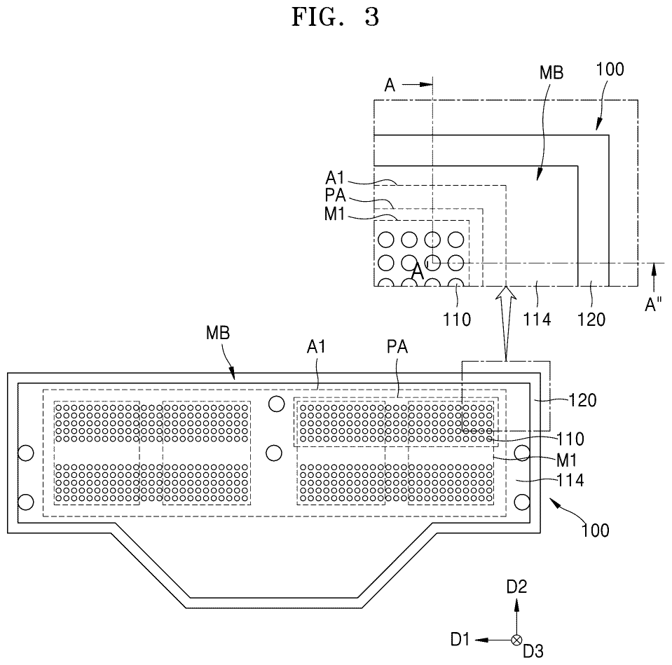

FIG. 1 is a diagram of a front surface of a memory module 1, according to an embodiment. FIG. 2 is a perspective view of the memory module 1 mounted on a compression mount connector CMC, according to an embodiment. FIG. 3 is a diagram of a rear surface of the memory module 1 and a partially enlarged view of the rear surface of the memory module 1, according to an embodiment.

Referring to FIGS. 1 through 3, the memory module 1 may include a module substrate 100 and a memory device M1 arranged on a front surface of the module substrate 100.

Although not illustrated in the drawings, one or more memory devices M1 may be arranged on a front surface MF of the module substrate 100, and a plurality of front surface connection pads electrically connected to the memory device M1 may be provided on the front surface MF of the module substrate 100. For example, the memory device M1 may be electrically connected to the plurality of front surface connection pads via solder balls or the like. Unlike a third metal layer 113, which is a surface of a plurality of rear surface connection pads 110 to be described below, that includes gold, the surfaces of the plurality of front surface connection pads may include copper.

The memory module 1 may include a low power compression attached memory module (LPCAMM2) that follows the joint electron device engineering council (JEDEC) standard. The one or more memory devices M1 included in the memory module 1 may include at least one of double data rate synchronous dynamic random access memory (DDR SDRAM), DDR2 SDRAM, DDR3 SDRAM, DDR4 SDRAM, DDR5 SDRAM, low power double data rate (LPDDR) SDRAM (LPDDR SDRAM), LPDDR2 SDRAM, LPDDR3 SDRAM, LPDDR4 SDRAM, LPDDR4X SDRAM, and/or LPDDR5 SDRAM.

The one or more memory devices M1 included in the memory module 1 may include memory devices, in which DRAM dies are stacked, such as a high bandwidth memory (HBM), HBM2, and HBM3. Types of the memory devices M1 included in the memory module 1 may be the same as or different from each other. In memory devices, in which one or more DRAM dies are stacked, electrical signals may be transceived via, for example, through-silicon vias (TSVs), wire bonding, vertical interconnectors, etc.

The type of the memory device M1 is not limited to the above, and any device capable of storing data may be included in the memory module 1. The number of memory devices M1 may be only an example, and the number of memory devices M1 may be determined according to a memory capacity provided to a user and capacity of each memory device M1.

Each of the one or more memory devices M1 constituting the memory module 1 may include a memory semiconductor chip. In other words, each of the memory devices M1 may include a semiconductor package including a memory chip. The memory device M1 may include one or more semiconductor substrates configured to include countless devices.

The semiconductor substrate included in the memory device M1 may include a semiconductor material, for example, silicon (Si) and germanium (Ge). The semiconductor substrate may include a conductive region, for example, a well doped with impurities, and may have various device isolation structures such as a shallow trench isolation (STI) structure.

The semiconductor substrate included in the memory device M1 may include various types of a plurality of individual devices. The plurality of individual devices may include, for example, a metal-oxide-semiconductor field effect transistor (MOSFET), such as a component metal-oxide-semiconductor (CMOS) transistor, an active device, a passive device, etc.

The memory module 1 may be divided into a first area A1, a second area A2, and a third area A3. The first area A1 may include an area including the plurality of memory devices M1, the second area A2 may include an area including an area, in which a semiconductor device including a power management integrated circuit (PMIC) is arranged, and the third area A3 may include an area including a memory controller. The third area A3 may be referred to as a serial presence detect (SPD) area. The SPD may include an electrically erasable programmable read-only memory (EPROM) chip, which stores characteristics and setting information of a memory module. The setting information may include parameters required for the memory controller to properly operate the memory module 1, and the parameters may include size, speed, voltage, timing information, or the like of the memory devices M1 included in the memory module.

The module substrate 100 may include a printed circuit board (PCB). The PCB may include a plurality of layers separated by a dielectric material, and on each layer, a power plane, a ground plane, and signal lines may be arranged.

A shape of the module substrate 100 in a plan view may have a shape in which a rectangular shape of the first area A1, in which the plurality of memory devices M1 are arranged, and a trapezoidal shape, in which the second area A2 including the PMIC and the third area A3 including the memory controller are arranged, are added together. For example, like illustrated in FIG. 1, the shape in a plan view may have a shape in which the second area A2 and the third area A3 including the memory controller are arranged on a relatively long side of the rectangular shape of the first area A1, that is, a shape in which a relatively long side is attached to the trapezoidal shape. The second area A2 and the third area A3 may be adjacent to each other, and the second area A2 and the third area A3 may be on one side surface of the first area A1 together. Alternatively, the shape in a plan view may protrude in one direction from an area where the first area A1 is arranged; the shape of the protruding area of the shape in a plan view may have a shape in which a width thereof decreases away from the first area A1; the second area A2 and the third area A3 may be arranged on the module substrate 100 in the protruding area; and the PMIC, the memory controller, or the like may be arranged on the module substrate 100 in the protruding area.

The memory module 1 may be arranged on a compression mount connector CMC. A plurality of rear surface connection pads on a base substrate BS may be electrically connected to the plurality of rear surface connection pads 110 on a rear surface MB of the memory module 1 via the compression mount connector CMC. The compression mount connector CMC may be provided with a connector pin MP including a plurality of pins. On the connector pin MP of the compression mount connector CMC, for example, a plurality of elastic pins may be provided, and a plurality of connector pins MP may be respectively arranged on a front surface and a rear surface of the compression mount connector CMC.

The connector pin MP may be arranged on the compression mount connector CMC according to arrangement positions of the plurality of rear surface connection pads 110 on the rear surface of the memory module 1. For example, because pad areas PA, in which the plurality of rear surface connection pads 110 are arranged, are divided into four portions, that is, in a 2×2 matrix, on the rear surface MB of the memory module 1 of FIG. 3, the connector pins MP of the compression mount connector CMC may be divided into four portions, that is in a 2×2 matrix, as illustrated in FIG. 2.

The compression mount connector CMC may be configured to electrically connect the plurality of rear surface connection pads 110 arranged on the rear surface MB of the memory module 1 to a plurality of connection pads arranged on the base substrate BS corresponding to the plurality of rear surface connection pads 110 on a one-to-one basis.

The plurality of connection pads arranged on the base substrate BS may be in contact with one ends of the plurality of pins of the compression mount connector CMC, and the plurality of rear surface connection pads 110 arranged on the rear surface MB of the memory module 1 may be in contact with the other ends of the plurality of pins of the compression mount connector CMC. By using a fastening effect of an external locking device, for example, a blot or the like, a force that is compressed to the memory module 1—the compression mount connector CMC—the base substrate BS may be applied. By using this force, the plurality of connection pads arranged on the base substrate BS may be electrically and stably connected to the plurality of rear surface connection pads 110 arranged on the rear surface MB of the memory module 1 via the compression mount connector CMC.

The base substrate BS may be referred to as a mother board or a main board. Although the illustration is omitted in FIG. 3, various electronic elements may be provided on the base substrate BS, the base substrate BS may provide an interface for installing a periphery device, and may generally include the PCB.

Referring to FIG. 3, the plurality of rear surface connection pads 110, an outer edge dummy layer 120, and a solder resist 114, which are provided on the rear surface MB of the module substrate 100, may be provided on the rear surface MB of the memory module 1. As described above, the pad areas PA, in which the plurality of rear surface connection pads 110 are arranged, may be distinguished from each other, and arranged on the rear surface MB of the memory module 1. The outer edge dummy layer 120 may be provided along the outer edge of the rear surface MB of the module substrate 100 of the memory module 1. The outer edge dummy layer 120 may be provided along at least a portion of the outer edge of the rear surface MB of the module substrate 100. Alternatively, as illustrated in FIG. 3, the module substrate 100 may extend continuously along the entire outer edge of the rear surface MB.

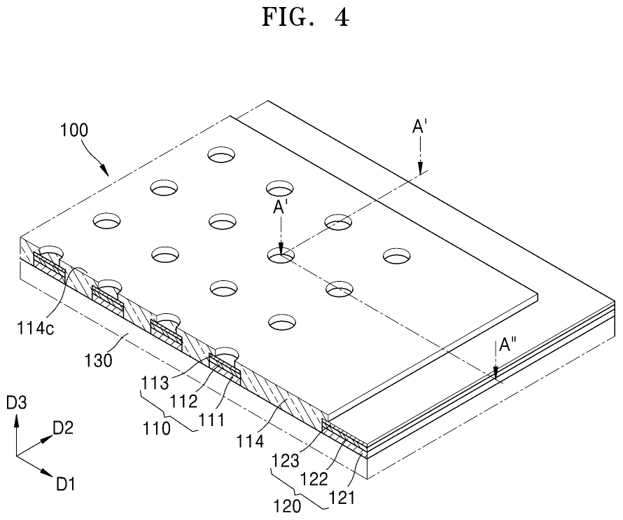

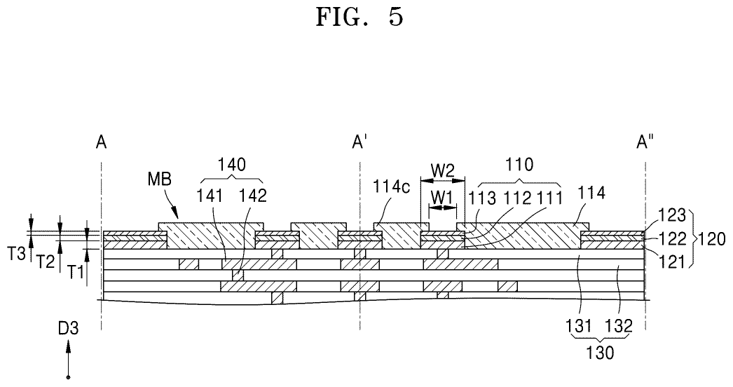

FIG. 4 is an enlarged perspective view of a portion of the module substrate 100 of the memory module 1, according to an embodiment. FIG. 4 is a cross-sectional view of the partially enlarged view of FIG. 3. FIG. 5 is a cross-sectional view of a cross-section of the module substrate 100 of the memory module 1, according to an embodiment. FIG. 5 is a cross-sectional view taken along line A-A′-A″ in FIG. 4.

Referring to FIGS. 4 and 5, the module substrate 100 may include an insulating layer 130 including a first insulating layer 131 and a second insulating layer 132, the plurality of rear surface connection pads 110 arranged on the insulating layer 130, the outer edge dummy layer 120, the solder resist 114, and a plurality of wirings 140 arranged in the insulating layer 130 and including a line pattern 141 and a via pattern 142. The plurality of rear surface connection pads 110 may be laterally spaced from the outer edge dummy layer 120 provided along the outer edge of the rear surface MB of the module substrate 100, and may be arranged relatively further inside the module substrate 100 than the outer edge dummy layer 120. The solder resist 114 may be arranged between the outer edge dummy layer 120 and the plurality of rear surface connection pads 110 on the insulating layer 130.

A body layer of the module substrate 100 may include the insulating layer 130 and the plurality of wirings 140. The insulating layer 130 may include the first insulating layer 131 and the second insulating layer 132. The plurality of wirings 140 may include a plurality of via patterns 142 provided to penetrate or extend through the first insulating layer 131, and a plurality of line patterns 141 provided inside the second insulating layer 132 or between the second insulating layer 132 and the first insulating layer 131. The plurality of via patterns 142 may penetrate or extend through one or more insulating layers 130, and may be configured to make vertical connections between the plurality of line patterns 141. For example, in the case of the module substrate 100 of the memory module 1, the module substrate 100 may include about 8 to about 12 layers of the PCBs.

The insulating layer 130 may include at least one material selected from phenol resin, epoxy resin, and/or polyimide. For example, the insulating layer 130 may include at least one material of prepreg, polyimide, flame retardant 4 (FR-4), tetrafunctional epoxy, polyphenylene ether, epoxy/polyphenylene oxide, bismaleimide triazine (BT), thermount, cyanate ester, and/or liquid crystal polymer.

The plurality of rear surface connection pads 110 may be arranged on the insulating layer 130, and electrically connected to the via pattern 142 provided in the first insulating layer 131. The plurality of rear surface connection pads 110 may include a first metal layer 111, a second metal layer 112, and the third metal layer 113. The outer edge dummy layer 120 may include a first outer edge metal layer 121, a second outer edge metal layer 122, and a third outer edge metal layer 123. Due to the process to be described below, the first metal layer 111 of the plurality of rear surface connection pads 110 and the first outer edge metal layer 121 of the outer edge dummy layer 120 may have the same vertical thickness and may comprise the same material. This is because they are formed by using the same process according to some embodiments.

Similarly, the second metal layer 112 of the plurality of rear surface connection pads 110 and the second outer edge metal layer 122 of the outer edge dummy layer 120 may have the same vertical thickness and may comprise the same material, and the third metal layer 113 of the plurality of rear surface connection pads 110 and the third outer edge metal layer 123 of the outer edge dummy layer 120 may have the same vertical thickness and may comprise the same material. The first metal layer 111 and the first outer edge metal layer 121 may include copper (Cu), the second metal layer 112 and the second outer edge metal layer 122 may include nickel (Ni), and the third metal layer 113 and the third outer edge metal layer 123 may include gold (Au).

A first thickness T1, which is the thickness of the first metal layer 111, may be greater than a second thickness T2, which is the thickness of the second metal layer 112, and the second thickness T2 may be greater than a third thickness T3, which is the thickness of the third metal layer 113. For example, the first metal layer 111 may have the first thickness T1 of about 15 μm to about 30 μm. The first thickness T1 of the first metal layer 111 may vary according to the forming method of the first metal layer 111. For example, the second thickness T2 of the second metal layer 112 may be about 2 μm to about 10 μm. For example, the third metal layer 113 may have a third thickness T3 of about 0.7 μm to about 3.0 μm. The third metal layer 113 may be formed by using a hard gold plating process, as described below. Accordingly, the thickness of the third metal layer 113 may be about 0.7 μm to about 3.0 μm, as described above. Furthermore, the first thickness T1, the second thickness T2, and the third thickness T3 may be in order from large thickness.

A thickness of the solder resist 114 may be greater than a vertical thickness of the plurality of rear surface connection pads 110, that is a combined thickness of the first thickness T1, the second thickness T2, and the third thickness T3. The solder resist 114 may be on and may cover at least a portion of an upper surface of the rear surface connection pad 110. In other words, the solder resist 114 may be on and may cover at least a portion of a surface of the third metal layer 113. For example, as illustrated in FIG. 4, the solder resist 114 may enter the inside of the upper surface of the plurality of rear surface connection pads 110, and uniformly cover the upper surface of the plurality of rear surface connection pads 110 along the outer edge of the upper surface of the plurality of rear surface connection pads 110. The upper surface the plurality of rear surface connection pads 110 may include one surface of the third metal layer 113. The solder resist 114 at least partially covering the upper surface of the plurality of rear surface connection pads 110 may be referred to as a first cover solder resist 114C. In other words, a first width W1, which is a horizontal width of the plurality of rear surface connection pads 110 exposed to the outside by the first cover solder resist 114C, may be less than a second width W2, which is a horizontal width of the plurality of rear surface connection pads 110.

The solder resist 114 may be in contact with the side surfaces of the plurality of rear surface connection pads 110. The solder resist 114 may be in contact with side surfaces of each of the first metal layer 111, the second metal layer 112, and the third metal layer 113, which constitute the plurality of rear surface connection pads 110. For example, as illustrated in FIG. 5, the solder resist 114 may be on and may cover all of the side surfaces of the first metal layer 111, the second metal layer 112, and the third metal layer 113. In this manner, the first metal layer 111, the second metal layer 112, and the third metal layer 113 may be at least partially blocked from the outside by the solder resist 114. In addition, due to the first cover solder resist 114C described above, an inflow of external materials or the like between the solder resist 114 and the plurality of rear surface connection pads 110 may be at least partially blocked.

The outer edge dummy layer 120 may not be connected to the plurality of wirings 140. In other words, an electrical signal may not pass through or reach the outer edge dummy layer 120. As in the manufacturing process of the module substrate 100 to be described below, the first outer metal layer 121 of the outer dummy layer 120 may have originally been integrated with the first metal layer 111 of the plurality of rear connection pads 110, but due to Cu etching during the manufacturing process of the module substrate 100, the first outer edge metal layer 121 of the outer edge dummy layer 120 may have been cut off and separated from the first metal layer 111 of the plurality of rear surface connection pads 110.

An existing hard gold plating process may deposit Ni on a surface by using an electroplating method, and then deposit gold on a Ni layer by using an electroplating method. In the gold plating process, because electroplating is performed by using current, in the existing hard gold plating process, the gold plating may be performed on the surface where nickel is arranged by using a plating bar. In the hard gold plated product manufactured by using the gold plating process, the plating bar may be provided, and the plating bar may be electrically connected to, for example, wirings provided in the PCB.

The module substrate 100 of the memory module 1 according to embodiments of the inventive concept may be characterized in that the third metal layer 113 of the plurality of rear surface connection pads 110 formed by using the hard gold plating process may not be electrically connected to the third outer edge metal layer 123 of the outer edge dummy layer 120 due to the result of the processes described below.

In the case of a memory module having an LPCAMM2 specifications, because the plating bar is not arranged on the rear surface of the memory module, performing the hard gold plating process may be limited. In addition, the rear surface of the memory module having the LPCAMM2 specifications may be formed by using an electroless nickel immersion gold (ENIG) process. Even though a portion of the surface, where the ENIG process has been performed and an exposure of the portion to the outside is unnecessary, is applied with a solder resist to block from the outside, and the rear surface connection pad or the like, where the exposure thereof to the outside is necessary, is not applied with the solder resist to expose the rear surface connection pad or the like to the outside, corrosion on the surface on which the ENIG process has been performed may occur.

Corrosion may occur in particular usage environments of a memory module due to corrosion causative substances, such as sulfur dioxide (SO₂), hydrogen sulfide (H₂S), chlorine (Cl₂), and nitrogen dioxide (NO₂). The thickness of a gold plated layer on the printed circuit board may be generally formed in the range of about 0.05 μm to about 0.1 μm, during the gold plating process performed by using the ENIG process. Alternatively, on the PCB, the thickness of the gold plated layer manufactured by using the ENIG may be limited to a maximum of about 0.5 μm, due to process characteristics of the ENIG.

When the thickness of the plated gold on the PCB, after the ENIG process is performed, is excessively large, the adhesion force between the gold plated layer and the nickel layer may be weakened and, accordingly, the gold plating result may be defective. In addition, nickel may reduce or prevent diffusion between the ENIG layer and copper, and when the gold plated layer is excessively thick, nickel may not be able to prevent the diffusion between the ENIG layer and copper. In addition, due to the characteristics of the ENIG process, when the thickness of the gold plated layer is excessively large, it may be difficult to secure the flatness of the surface of the gold plated layer.

When the ENIG process is performed on a PCB, the IPC-4552 standard is generally observed, and the IPC-4552 standard recommends the thickness of the gold plated layer from about 0.04 μm to about 0.1 μm. When the rear surface of a memory module is plated by using the ENIG process, corrosion may occur in copper located inside the surface where the gold plating has been performed. When a memory module is exposed to the corrosion causative substance, the gold plated layer manufactured by the ENIG process may cause a reliability issue based on the corrosion. The reason may be that because the corrosion causative substance is a gas, the corrosion causative substance penetrates a thin gold plated layer formed by using the ENIG process, and corrodes copper.

In the memory module 1 according to embodiments of the inventive concept, because the third metal layer 113 of the plurality of rear surface connection pads 110 of the rear surface MB of the module substrate 100 is formed by using the hard gold plating process, a gold plated layer thicker than about 0.5 μm, which is the substantially maximum thickness of the gold plated layer formed by using the ENIG process, may be formed. For example, the third thickness T3 of the third metal layer 113 of the plurality of rear surface connection pads 110 of the rear surface MB of the module substrate 100 formed by using the hard gold plating process may be formed to be about 0.7 μm to about 3.0 μm. In other embodiments, the third thickness T3 of the third metal layer 113 may be formed greater than the third thickness T3, as necessary.

In the memory module 1 according to embodiments of the inventive concept, the third metal layer 113 of the rear surface connection pad 110 may be formed large by using the hard gold plating process. In addition, in the memory module 1 according to embodiments of the inventive concept, a solder resist 114, which is not applied in an existing LPCAMM2, may be applied to the rear surface of the module substrate 100, so that the solder resist 114 at least partially surrounds the sides of the plurality of rear surface connection pads 110, and a portion of the upper surface of the plurality of rear surface connection pads 110.

By using the thickness of the third metal layer 113 and the arrangement of the solder resist 114, the possibility of corrosion that may occur by the corrosion causative substance penetrating the third metal layer 113, which is the gold plated layer, and the possibility of corrosion, that may occur by the corrosion causative substance penetrating the side surfaces of the plurality of rear surface connection pads 110, may be reduced. Thus, the corrosion reliability of the memory module 1 according to embodiments of the inventive concept may be improved.

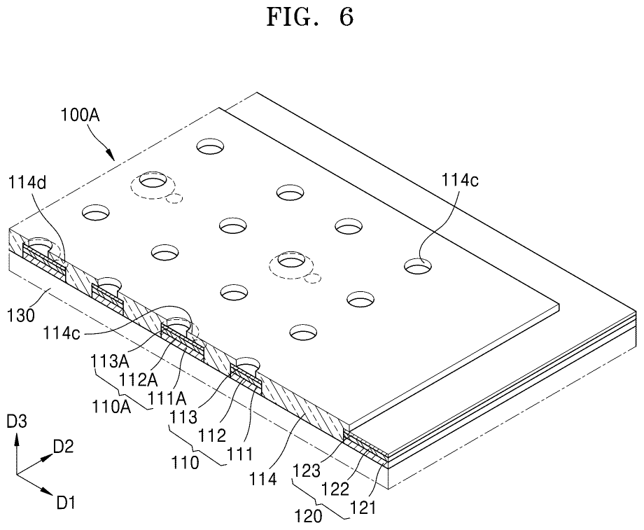

FIG. 6 is an enlarged perspective view of a portion of a module substrate 100A of the memory module 1, according to an embodiment.

Referring to FIG. 6, a plurality of rear surface connection pads of the module substrate 100A included in the memory module 1 may include the plurality of rear surface connection pads 110 and a plurality of second rear surface connection pads 110A. Similar to the first metal layer 111, the second metal layer 112, and the third metal layer 113 of the plurality of rear surface connection pads 110 described above, the plurality of second rear surface connection pads 110A may include a first metal layer 111A, a second metal layer 112A, and a third metal layer 113A. Descriptions of the thicknesses and the constituent materials of the plurality of second rear surface connection pads 110A may be the same as those of the first metal layer 111, the second metal layer 112, and the third metal layer 113 of the plurality of rear surface connection pads 110, respectively.

The shape of the plurality of second rear surface connection pads 110A in a plan view may have a shape in which a circular shape partially overlaps another circular shape smaller than the circular shape. The plurality of second rear surface connection pads 110A may serve as signal pads, and the plurality of rear surface connection pads 110 may serve as ground pads.

At least a portion of a plurality of rear surface connection pads may include the plurality of second rear surface connection pads 110A, two second rear surface connection pads 110A among a total of sixteen rear surface connection pads are illustrated in FIG. 6, and the rear surface connection pads 110 and the second rear surface connection pads 110A are illustrated as alternately arranged as an example, but the arrangement of the rear surface connection pads 110 and the second rear surface connection pads 110A may vary as necessary.

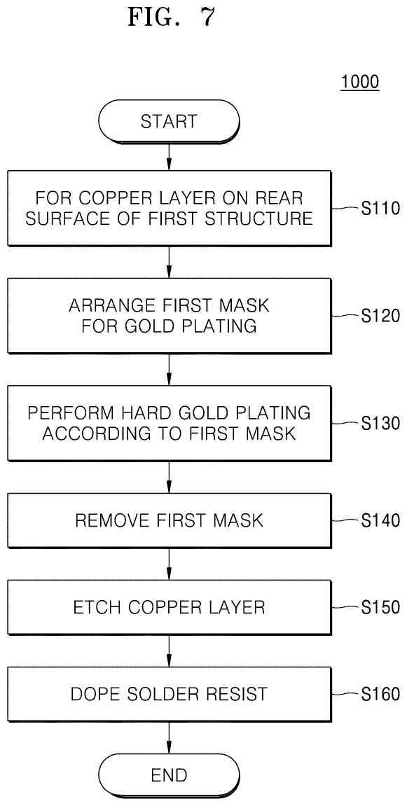

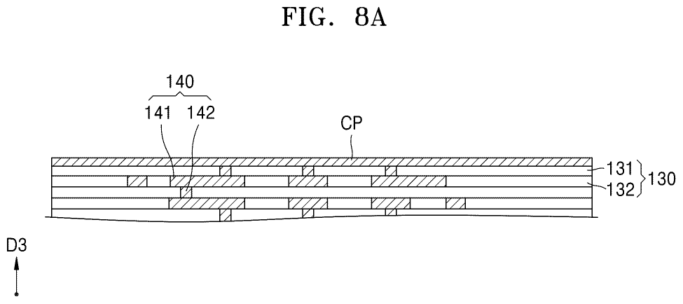

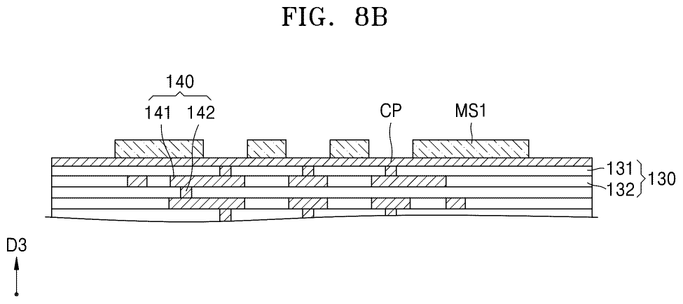

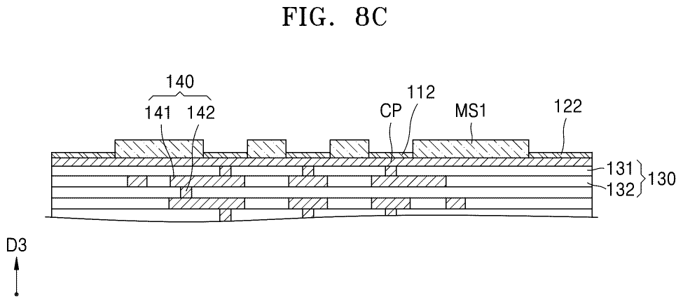

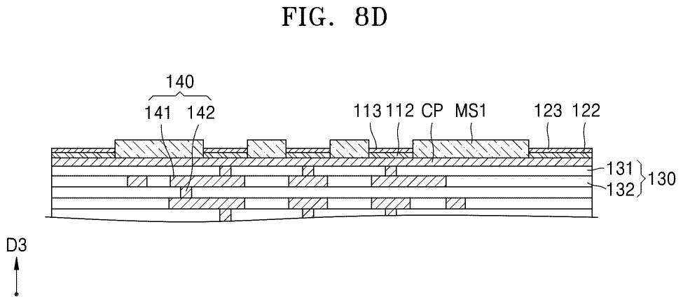

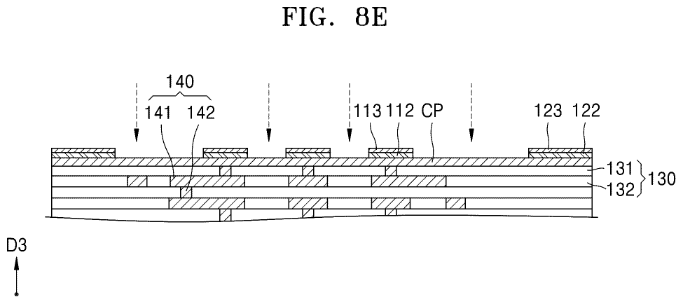

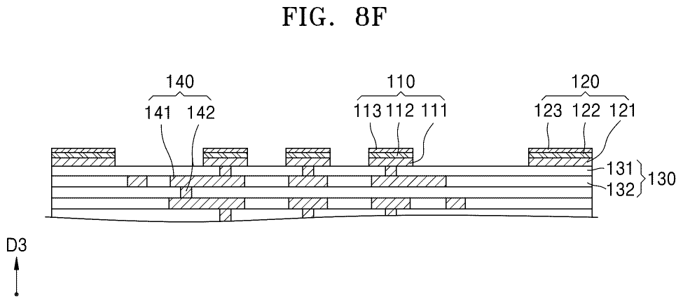

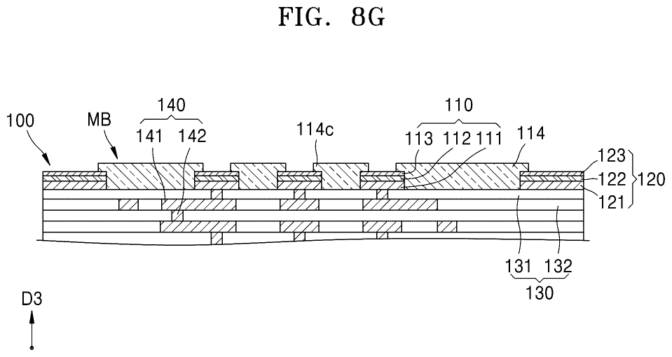

FIG. 7 is a flowchart describing a manufacturing method 1000 of the module substrate 100 of the memory module 1, according to an embodiment. FIGS. 8A through 8G are cross-sectional views sequentially illustrating the manufacturing method 1000 of the module substrate 100 of the memory module 1, according to embodiments. FIGS. 8A through 8G are cross-sectional views taken along portion A-A′-A″ in FIG. 4, which are illustrated according to a sequence of the manufacturing method 1000 of the module substrate 100.

Referring to FIG. 7, a copper layer may be formed on a rear surface of a body layer including the insulating layer 130 and the plurality of wirings 140 formed in the insulating layer 130 (S110). The body layer may be referred to as a first structure. Next, a first mask for the hard gold plating process may be arranged (S120). The hard gold plating process may be performed by using the first mask (S130). In operation S130, a layer including nickel and a layer including gold may be formed on the copper layer. Next, the first mask may be removed (S140). The copper layer may be at least partially exposed after the first mask is etched (S150). Next, the solder resist may be applied to the rear surface of a body layer (S160). By performing these processes, the module substrate 100 of the memory module 1 according to embodiments of the inventive concept may be manufactured. A more detailed manufacturing method 1000 of the module substrate 100 of the memory module 1 is described together with the diagrams in FIGS. 8A through 8G is described below.

Referring to FIG. 8A, a copper layer CP may be formed on the rear surface of the body layer including the insulating layer 130 and the plurality of wirings 140 formed inside the insulating layer 130. The copper layer CP may be referred to as a copper thin layer. In some embodiments, a front surface of the body layer may also form a copper layer together with the copper layer CP. When a process on the front surface of the body layer is completed, wirings including a plurality of front surface connection pads to be connected to the memory device M1 may be formed. Next, a treatment using an acidic solution or the like may be performed to remove an oxide layer on a surface of the copper layer CP may be performed before an electrolytic nickel plating process is completed.

However, in the manufacturing process of the module substrate 100 for the front surface of the body layer, a first mask MS1 to be described below may be on and cover the entire front surface of the body layer. Because the first mask MS1 covers the entire front surface of the body layer, a metal layer including a separate nickel and a metal layer including gold may not be formed. Accordingly, because the gold plating process is not performed on the front surface of the body layer, a plurality of front surface connection pads including copper may be observed on the front surface MF of the completed module substrate 100.

Referring to FIG. 8B, the first mask MS1 may be arranged on the copper layer CP, except locations where the plurality of rear surface connection pads 110 and the outer edge dummy layer 120 are to be formed as illustrated in FIG. 5.

Referring to FIG. 8C, in a state where the first mask MS1 is arranged on the copper layer CP, the second metal layer 112 and the second outer edge metal layer 122 may be formed on portions of the copper layer CP exposed to the outside. The second metal layer 112 and the second outer edge metal layer 122 may include nickel as described above, and may be formed by using an electroplating process. The plating bar for performing the hard gold plating process may not be provided on the rear surface of a memory module having the LPCAMM2 specifications. In the manufacturing method 1000 of the module substrate 100 of the memory module 1 according to embodiments of the inventive concept, by supplying a current to the first outer edge metal layer 121 or the first metal layer 111 included in an outer edge metal layer, an electroplating process for forming the second metal layer 112 and the second outer edge metal layer 122 may be performed.

Referring to FIG. 8D, the third metal layer 113 and the third outer edge metal layer 123 may be formed on the formed second metal layer 112 and the second outer edge metal layer 122. As described above, both the third metal layer 113 and the third outer edge metal layer 123 may include gold. The third metal layer 113 and the third outer edge metal layer 123 may be formed by using an electrolysis gold plating process. As described with reference to FIG. 8C, because the plating bar for performing the hard gold plating process is not provided on the rear surface of a memory module having the LPCAMM2 specifications, by supplying a current to the second outer edge metal layer 122 or the second metal layer 112 included in an outer edge metal layer, an electroplating process may be performed to form the third metal layer 113 and the third outer edge metal layer 123.

Referring to FIGS. 8E and 8F, the first mask MS1 may be removed. The first mask MS1 may be stripped by using a photosensitive agent remover or the like. The first mask MS1 may be removed, and portions of the copper layer CP may be exposed to the outside. In FIG. 8E, a copper etching process may be performed to remove the copper layer CP exposed to the outside at portions indicated by arrows.

Referring to FIG. 8G, the solder resist 114 may be patterned to be on and cover the side surfaces of the outer edge dummy layer 120, the side surfaces of the plurality of rear surface connection pads 110, and portions of the upper surface of the plurality of rear surface connection pads 110. By performing these processes, the module substrate 100 of the memory module 1 according to embodiments of the inventive concept may be manufactured.

While the inventive concept has been particularly shown and described with reference to embodiments thereof, it will be understood that various change in form and details may be made therein without departing from the spirit and scope of the following claims.

What is claimed is:

1. A memory module comprising:
a module substrate; and
a memory device on a front surface of the module substrate,
wherein the module substrate comprises a plurality of insulating layers, a plurality of wirings inside the plurality of insulating layers, a plurality of rear surface connection pads on the plurality of insulating layers on a rear surface, which is opposite to the front surface of the module substrate, an outer edge dummy layer on the plurality of insulating layers, and a solder resist on the plurality of insulating layers,
wherein the plurality of rear surface connection pads comprise a first metal layer, a second metal layer, and a third metal layer, and the first metal layer, the second metal layer, and the third metal layer are sequentially stacked from the plurality of insulating layers,
wherein the first metal layer, the second metal layer, and the third metal layer comprise different materials from one another,
wherein the outer edge dummy layer extends along an outer edge of the rear surface of the module substrate,
wherein the plurality of rear surface connection pads are configured to contact a plurality of connector pins, respectively, which are provided in an external compression mounting connector, and
wherein a thickness of the third metal layer is about 0.7 μm to about 3.0 μm in a direction perpendicular to the front surface of the module substrate.

2. The memory module of claim 1,
wherein the first metal layer comprises copper, the second metal layer comprises nickel, and the third metal layer comprises gold,
wherein the outer edge dummy layer comprises a first outer edge metal layer, a second outer edge metal layer, and a third outer edge metal layer,
wherein the first outer edge metal layer, the second outer edge metal layer, and the third outer edge metal layer are sequentially stacked from the plurality of insulating layers, and
wherein the first outer edge metal layer comprises copper, the second outer edge metal layer comprises nickel, and the third outer edge metal layer comprises gold.

3. The memory module of claim 1, wherein
the outer edge dummy layer is laterally spaced apart from the plurality of rear surface connection pads, and is not electrically connected to the plurality of rear surface connection pads and the plurality of wirings.

4. The memory module of claim 1, wherein the outer edge dummy layer continuously extends along an entire outer edge of the module substrate.

5. The memory module of claim 1, wherein the memory device is not on the rear surface of the module substrate.

6. The memory module of claim 1,
wherein a first area comprising an area where the memory device is arranged, a second area, and a third area are provided on a front surface of the module substrate,
wherein the second area comprises a memory controller chip, and the third area comprises a power management integrated circuit (PMIC), and
wherein the second area is adjacent to the third area, and the second area and the third area are arranged on one side of the first area.

7. The memory module of claim 6, wherein
at least portions of the plurality of rear surface connection pads overlap the first area in the direction perpendicular to the front surface of the module substrate, and all of the plurality of rear surface connection pads do not overlap the second area and the third area in the direction perpendicular to the front surface of the module substrate.

8. The memory module of claim 1, wherein a thickness increases in an order of the first metal layer, the second metal layer, and the third metal layer in the direction perpendicular to the front surface of the module substrate.

9. The memory module of claim 2, wherein
a thickness of the first outer edge metal layer is equal to a thickness of the first metal layer in the direction perpendicular to the front surface of the module substrate, a thickness of the second outer edge metal layer is equal to a thickness of the second metal layer in the direction perpendicular to the front surface of the module substrate, and a thickness of the third outer edge metal layer is equal to a thickness of the third metal layer in the direction perpendicular to the front surface of the module substrate.

10. The memory module of claim 2, wherein
a material included in the first outer edge metal layer is same as a material included in the first metal layer, a material included in the second outer edge metal layer is same as a material included in the second metal layer, a material included in the third outer edge metal layer is same as a material included in the third metal layer.

11. The memory module of claim 1, wherein
a thickness of the solder resist in the direction perpendicular to the front surface of the module substrate is greater than a thickness of the plurality of rear surface connection pads in the direction perpendicular to the front surface of the module substrate, and all of side surfaces of the plurality of rear surface connection pads are configured to be in contact with the solder resist.

12. The memory module of claim 11, wherein the solder resist is on at least a portion of one surface of the third metal layer of the plurality of rear surface connection pads.

13. The memory module of claim 1, wherein
a plurality of front surface connection pads configured to be connected to the memory device are on the front surface of the module substrate, and surfaces of the plurality of front surface connection pads comprise copper.

14. The memory module of claim 1, wherein
an area of at least portions of the plurality of rear surface connection pads has a circular shape in a plan view in which the circular shape partially overlaps another circular shape smaller than the circular shape.

15. A memory module comprising:
a module substrate;
a plurality of memory devices on a front surface of the module substrate; and
power management integrated circuits (PMICs) spaced apart from each other in one side direction of the plurality of memory devices and adjacent to each other, and a memory controller chip,
wherein the module substrate comprises a plurality of insulating layers, a plurality of wirings inside the plurality of insulating layers, a plurality of rear surface connection pads on the plurality of insulating layers on a rear surface of the module substrate, which is opposite to the front surface of the module substrate, an outer edge dummy layer on the plurality of insulating layers, and a solder resist on the plurality of insulating layers,
wherein the plurality of rear surface connection pads comprise a plurality of first rear surface connection pads and a plurality of second rear surface connection pads,
wherein an area of the plurality of second rear surface connection pads is a circular shape in a plan view of the memory module,
wherein the circular shape partially overlaps another circular shape smaller than the circular shape,
wherein the plurality of rear surface connection pads comprise a first metal layer, a second metal layer, and a third metal layer, the first metal layer, the second metal layer, and the third metal layer are sequentially stacked from the plurality of insulating layers, and the first metal layer comprises copper, the second metal layer comprises nickel, and the third metal layer comprises gold,
wherein the outer edge dummy layer is laterally spaced apart from the plurality of rear surface connection pads, and continuously extends along an entire outer edge of the rear surface of the module substrate,
wherein the outer edge dummy layer is not electrically connected to the plurality of rear surface connection pads and the plurality of wirings,
wherein the plurality of rear surface connection pads are configured to contact a plurality of connector pins in an external compression mounting connector, respectively, and
wherein a thickness of the third metal layer is about 0.7 μm to about 3.0 μm in a direction perpendicular to the front surface of the module substrate.

16. The memory module of claim 15,
wherein the outer edge dummy layer comprises a first outer edge metal layer, a second outer edge metal layer, and a third outer edge metal layer,
wherein the first outer edge metal layer, the second outer edge metal layer, and the third outer edge metal layer are sequentially stacked from the plurality of insulating layers,
wherein a thickness of the first outer edge metal layer in the direction perpendicular to the front surface of the module substrate is equal to a thickness of the first metal layer in a direction perpendicular to the front surface of the module substrate, a thickness of the second outer edge metal layer in the direction perpendicular to the front surface of the module substrate is equal to a thickness of the second metal layer in the direction perpendicular to the front surface of the module substrate, and a thickness of the third outer edge metal layer is equal to a thickness of the third metal layer in the direction perpendicular to the front surface of the module substrate, and
wherein a material included in the first outer edge metal layer is same as a material included in the first metal layer, a material included in the second outer edge metal layer is same as a material included in the second metal layer, a material included in the third outer edge metal layer is same as a material included in the third metal layer.

17. The memory module of claim 15,
wherein a thickness of the solder resist in the direction perpendicular to the front surface of the module substrate is greater than a thickness of the plurality of rear surface connection pads in the direction perpendicular to the front surface of the module substrate, and all side surfaces of the plurality of rear surface connection pads are configured to be in contact with the solder resist,
wherein the solder resist is on at least a portion of one surface of the third metal layer of the plurality of rear surface connection pads, and
wherein a plurality of front surface connection pads configured to be connected to the memory device on the front surface of the module substrate, and surfaces of the plurality of front surface connection pads comprise copper.

18. The memory module of claim 15,
wherein at least portions of the plurality of rear surface connection pads overlap the plurality of memory devices in the direction perpendicular to the front surface of the module substrate,
wherein both the PMIC and the memory controller chip do not overlap the plurality of rear surface connection pads in the direction perpendicular to the front surface of the module substrate, and
wherein the plurality of memory devices and passive devices are not on the rear surface of the module substrate.

19. The memory module of claim 15, wherein the plurality of first rear surface connection pads comprise signal pads, and the plurality of second rear surface connection pads comprise ground pads.

20. A memory module comprising:
a module substrate; and
a memory device on a front surface of the module substrate,
wherein the module substrate comprises a plurality of insulating layers, a plurality of wirings inside the plurality of insulating layers, a plurality of rear surface connection pads on the plurality of insulating layers on a rear surface, which is opposite to the front surface of the module substrate, an outer edge dummy layer on the plurality of insulating layers, and a solder resist on the plurality of insulating layers,
wherein the plurality of rear surface connection pads comprise a first metal layer, a second metal layer, and a third metal layer, and the first metal layer, the second metal layer, and the third metal layer are sequentially stacked from the plurality of insulating layers,
wherein the first metal layer comprises copper, the second metal layer comprises nickel, and the third metal layer comprises gold,
wherein the outer edge dummy layer extends along an outer edge of the rear surface of the module substrate,
wherein the plurality of rear surface connection pads are configured to contact a plurality of connector pins in an external compression mounting connector, respectively,
wherein a thickness of the third metal layer is about 0.7 μm to about 3.0 μm in a direction perpendicular to the front surface of the module substrate,
wherein the outer edge dummy layer comprises a first outer edge metal layer, a second outer edge metal layer, and a third outer edge metal layer,
wherein the first outer edge metal layer, the second outer edge metal layer, and the third outer edge metal layer are sequentially stacked from the plurality of insulating layers,
wherein the first outer edge metal layer comprises copper, the second outer edge metal layer comprises nickel, and the third outer edge metal layer comprises gold,
wherein the outer edge dummy layer is laterally spaced apart from the plurality of rear surface connection pads, is not electrically connected to the plurality of rear surface connection pads and the plurality of wirings, and continuously extends along an entire outer edge of the module substrate,
wherein the memory device is not on the rear surface of the module substrate, and a first area, a second area, and a third area, which include an area in which the memory device is arranged, is on the front surface of the module substrate,
wherein the second area comprises a memory controller chip, the third area comprises a power management integrated circuit (PMIC), the second area is adjacent to the third area, and the second area and the third area are on one side of the first area,
wherein at least portions of the plurality of rear surface connection pads overlap the first area in the direction perpendicular to the front surface of the module substrate, and all of the plurality of rear surface connection pads do not overlap the second area and the third area in the direction perpendicular to the front surface of the module substrate,
wherein a thickness increases in an order of the first metal layer, the second metal layer, and the third metal layer in the direction perpendicular to the front surface of the module substrate,
wherein a material included in the first outer edge metal layer, a material included in the second outer edge metal layer, a material included in the third outer edge metal layer are identical to a material included in the first metal layer, a material included in the second metal layer, a material included in the third metal layer, respectively corresponding thereto, and
wherein a thickness of the solder resist in the direction perpendicular to the front surface of the module substrate is greater than a thickness of the plurality of rear surface connection pads in the direction perpendicular to the front surface of the module substrate, all side surfaces of the plurality of rear surface connection pads are in contact with the solder resist, and the solder resist is on at least a portion of one surface of the third metal layer of the plurality of rear surface connection pads.
